(19) United States
(12) Patent Application Publication
(10) Pub. No.: US 2025/0290994 A1
(43) Pub. Date: Sep. 18, 2025

(54) ELECTROLYTE FAULT PROGNOSTICS FOR LITHIUM-ION BATTERIES

(71) Applicant: GM GLOBAL TECHNOLOGY OPERATIONS LLC, Detroit, MI (US)

(72) Inventors: Xinyu Du, Oakland Township, MI (US); Huaizheng Mu, Troy, MI (US); Shengbing Jiang, Rochester Hills, MI (US); Rasoul Salehi, Ann Arbor, MI (US); Chaitanya Sankavaram, Rochester Hills, MI (US)

(21) Appl. No.: 18/605,053

(22) Filed: Mar. 14, 2024

(51) Int. Cl. G01R 31/392; B60L 3/00; B60L 58/12; B60L 58/16; G01R 31/396; H01M 10/42; H01M 10/46; H01M 10/48; H02J 7/00

(52) U.S. Cl. CPC G01R 31/392; B60L 3/0046; B60L 58/12; B60L 58/16; G01R 31/396; H01M 10/4228; H01M 10/46; H01M 10/482; H01M 10/486; H02J 7/005; H02J 7/0063; B60L 2240/545; H01M 2220/20

(57) ABSTRACT

A system includes a measurement module, a health indicator module, a normalization module, and a fault detection module. The measurement module is configured to measure a plurality of parameters associated with a battery comprising cells including an electrolyte. The health indicator module is configured to generate a plurality of health indicators based on the measured parameters. The normalization module is configured to normalize the health indicators and to combine the normalized health indicators into different sets to detect different types of faults associated with the electrolyte. The fault detection module is configured to detect one or more of the faults associated with the electrolyte based on one or more of the normalized health indicators in one or more of the sets.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to lithium-ion batteries and more particularly to electrolyte fault prognostics for lithium-ion batteries.

Lithium-ion batteries can be widely used in various applications. For example, lithium-ion batteries can be used to supply power to computing devices such as laptops, handheld devices (e.g., smartphones and tablets), and so on. Lithium-ion batteries can also be used to power vehicles such as electric vehicles (EVs); and other equipment such as lawncare equipment such as lawnmowers, snow blowers, trimmers, and so on.

### SUMMARY

A system comprises a measurement module, a health indicator module, a normalization module, and a fault detection module. The measurement module is configured to measure a plurality of parameters associated with a battery comprising cells including an electrolyte. The health indicator module is configured to generate a plurality of health indicators based on the measured parameters. The normalization module is configured to normalize the health indicators and to combine the normalized health indicators into different sets to detect different types of faults associated with the electrolyte. The fault detection module is configured to detect one or more of the faults associated with the electrolyte based on one or more of the normalized health indicators in one or more of the sets.

In other features, the types of faults associated with the electrolyte comprise a first fault due to the electrolyte leaking from one or more of the cells, a second fault due to moisture seeping into one or more of the cells, and a third fault due to the electrolyte aging in one or more of the cells.

In other features, the battery comprises a plurality of modules, each module comprising a plurality of groups of cells, and each group comprising one or more of the cells. The fault detection module is configured to detect one or more of the faults associated with the electrolyte in one of the groups of cells.

In other features, the battery comprises a plurality of modules, each module comprising groups of cells, and each group comprising one or more of the cells. The normalization module is configured to normalize one of the health indicators for one of the groups of cells in one of the modules by subtracting a median value of the one of the health indicators for the one of the modules from the one of the health indicators for the one of the groups of cells. The health indicator module is configured to generate the one of the health indicators and the median value of the one of the health indicators based on the parameters measured in the same charge/discharge cycle of the battery.

In other features, the fault detection module is configured to detect one of the faults based on one or more of the normalized health indicators in one of the sets exceeding a respective predetermined threshold and to generate an alert upon detecting the one of the faults.

In other features, the fault detection module is configured to determine a health of the battery based on which of the faults is detected and which of the normalized health indicators exceed respective predetermined thresholds.

In other features, the battery comprises a plurality of modules, each module comprising groups of cells, and each group comprising one or more cells. The measurement module is configured to measure the parameters including a current through the battery, voltages across each group of cells, temperatures of each group of cells, and a state of charge of the battery. The health indicator module is configured to generate the health indicators for each group of cells. The normalization module is configured to normalize each of the health indicators for one of the groups of cells based on median values of each of the health indicators for the one of the groups of cells.

In other features, one of the sets of the normalized health indicators for detecting a fault due to the electrolyte leaking from one or more of the cells comprises: (i) a static resistance of the battery during a discharge cycle of the battery, (ii) a variation in capacity of the battery during constant current charging of the battery, (iii) a position of a peak value of dQ/dV relative to voltage V of the battery during constant current charging of the battery, (iv) a difference in energy between charging and discharging cycles of the battery, and (v) an ohmic internal resistance of the battery during charging and discharging of the battery.

In other features, one of the sets of the normalized health indicators for detecting a fault due to moisture seeping into one or more of the cells comprises: (i) a variation in capacity of the battery during constant current charging of the battery, (ii) a difference in energy between charging and discharging cycles of the battery, (iii) a discharge duration for the battery, (iv) a sum of voltages of the battery during constant current charging of the battery, (v) a peak value of dQ/dV relative to voltage V of the battery during constant current charging of the battery, and (vi) a polarization resistance during charging and discharging of the battery.

In other features, one of the sets of the normalized health indicators for detecting a fault due to the electrolyte aging in one or more of the cells comprises: (i) a variation in capacity of the battery during constant current charging of the battery, (ii) a discharge duration for the battery, (iii) a sum of voltages of the battery during constant current charging of the battery, (iv) a difference in energy between charging and discharging cycles of the battery, (v) a difference in capacity of the battery during charging and discharging of the battery, (vi) a rate of change of voltage of the battery during constant current charging of the battery, (vii) a logarithmic rate of change of current during constant voltage charging of the battery, (viii) loss of capacity of anode during constant current charging of the battery, (ix) loss of capacity of cathode during constant current charging of the battery, (x) loss of lithium inventory during constant current charging of the battery, and (xi) an ohmic internal resistance of the battery during charging and discharging of the battery.

In other features, a vehicle comprises the battery and the system. The fault detection module is configured to output an indication of the one or more of the faults associated with the electrolyte to control power supplied from the battery to one or more subsystems of the vehicle.

In still other features, a method comprises measuring a plurality of parameters associated with a battery comprising cells including an electrolyte, and generating a plurality of health indicators based on the measured parameters. The method comprises normalizing the health indicators and to combine the normalized health indicators into different sets to detect different types of faults associated with the electrolyte, and detecting one or more of the faults associated with the electrolyte based on one or more of the normalized health indicators in one or more of the sets.

In other features, the types of faults associated with the electrolyte comprise a first fault due to the electrolyte leaking from one or more of the cells, a second fault due to moisture seeping into one or more of the cells, and a third fault due to the electrolyte aging in one or more of the cells.

In other features, the battery comprises a plurality of modules, each module comprising a plurality of groups of cells, and each group comprising one or more of the cells. The method further comprises detecting one or more of the faults associated with the electrolyte in one of the groups of cells.

In other features, the battery comprises a plurality of modules, each module comprising groups of cells, and each group comprising one or more of the cells. The method further comprises normalizing one of the health indicators for one of the groups of cells in one of the modules by subtracting a median value of the one of the health indicators for the one of the modules from the one of the health indicators for the one of the groups of cells.

In other features, the method further comprises generating the one of the health indicators and the median value of the one of the health indicators based on the parameters measured in the same charge/discharge cycle of the battery.

In other features, the method further comprises detecting one of the faults based on one or more of the normalized health indicators in one of the sets exceeding a respective predetermined threshold and to generate an alert upon detecting the one of the faults.

In other features, the method further comprises determining a health of the battery based on which of the faults is detected and which of the normalized health indicators exceed respective predetermined thresholds.

In other features, the battery comprises a plurality of modules, each module comprising groups of cells, and each group comprising one or more cells. The method further comprises measuring the parameters including a current through the battery, voltages across each group of cells, temperatures of each group of cells, and a state of charge of the battery. The method further comprises generating the health indicators for each group of cells, and normalizing each of the health indicators for one of the groups of cells based on median values of each of the health indicators for the one of the groups of cells.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example of a lithium-ion battery;

FIG. 1B shows an example of a cell of the lithium-ion battery of FIG. 1A;

FIG. 2 shows an example of a system comprising a vehicle that uses the lithium-ion battery of FIG. 1A and that uses a prognostic method of the present disclosure to detect faults in electrolyte used in the lithium-ion battery of FIG. 1A;

FIG. 3 shows an example of a control module of the vehicle of FIG. 2 that uses the prognostic method to detect faults in electrolyte used in cells of the lithium-ion battery of FIG. 1A;

FIG. 4 shows an example of the prognostic method performed by the control module of the vehicle of FIG. 2 to detect faults in electrolyte used in cells of the lithium-ion battery of FIG. 1A;

FIG. 5 shows an example of a graph of current versus time during charging and discharging cycles of the lithium-ion battery of FIG. 1A;

FIG. 6 shows an example of an equivalent circuit model (ECM) of the lithium-ion battery of FIG. 1A;

FIG. 7 shows an example of a normalization method used by the prognostic method to normalize health indicators of the cells of the lithium-ion battery of FIG. 1A to detect faults in electrolyte used in cells of the lithium-ion battery of FIG. 1A; and

FIG. 8 shows an example of a method used by the prognostic method to declare a fault and a failure mode of the electrolyte used in cells of the lithium-ion battery of FIG. 1A.

In the drawings, reference numbers may be reused to identify similar and/or identical elements.

### DETAILED DESCRIPTION

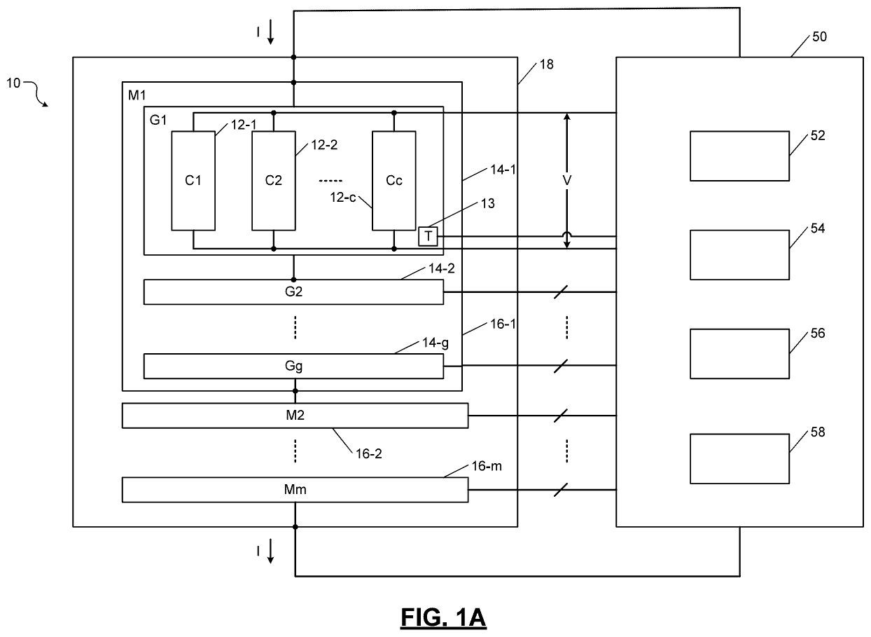

The present disclosure provides a prognostic method for detecting different faults (failure modes) of electrolyte in lithium-ion batteries. The prognostic method uses various health indicators derived from current, voltage, temperature, and state of charge (SOC) measurements of the battery as described below in detail. Initially, before describing the prognostic method, an example of a battery and a cell of the battery are shown and described below with reference to FIGS. 1A and 1B.

FIGS. 1A and 1B schematically show an example of a lithium-ion battery 10 and a cell 12 of the lithium-ion battery 10, respectively. In FIG. 1A, for example, the lithium-ion battery 10 (hereinafter the battery 10) comprises a pack comprising a plurality of modules, where each module comprises a plurality of groups of cells. For example, in a group of cells, one or more cells C1, C2, . . . , Cc, which are respectively identified at 12-1, 12-2, . . . , 12-c, where c is an integer greater than or equal to 1 (collectively called the cells 12) are connected in parallel to each other. In a module, a plurality of groups of cells 12 G1, G2, . . . , Gg, which are respectively identified at 14-1, 14-2, . . . , 14-g, where g is an integer greater than 1 (collectively called the groups 14 or the cell groups 14) are connected in series with each other. In a pack called P and identified at 18, a plurality of modules M1, M2, . . . , Mm, which are identified at 16-1, 16-2, . . . , 16-m, where m is an integer greater than 1 (collectively called the modules 16 or the cell modules 16) are connected in series with each other. In each group 14, a temperature sensor T identified at 13 can be disposed. Alternatively or additionally, while not shown, one or more temperature sensors can also be disposed in each module 16.

In some batteries, the pack 18 may not comprise multiple modules 16 in the pack 18. Instead, the groups 14 of cells 12 are connected to each other in series and are arranged in the pack 18 instead of in multiple modules 16. Thus, in these batteries, the pack 18 is the same as a single module 16, and m=1. In the following description, the prognostic method computes median values of health indicators for each module 16 to normalize the health indicators for each group 14 in the corresponding module 16. Instead, when the pack 18 comprises the groups 14 and functions as a single module 16, the median values of the health indicators can be computed for the pack 18 just as the median values are computed for a module 16. Then the health indicators for each group 14 in the pack 18 can be normalized using the median values of the health indicators computed for the pack 18.

While not shown, in some batteries, a plurality of packs such as the pack 18 can be connected in series or parallel with each other or using a combination of series and parallel connections, which connections can be switched between series and parallel connections depending on power requirements of one or more loads. For simplicity of discussion, the battery 10 is presumed to comprise the pack 18 although the present disclosure is not so limited and can be extended to batteries comprising multiple packs.

A measurement module 50 can be connected across the pack 18 (i.e., across the battery 10) to measure current, voltage, temperature, and to estimate SOC of the battery 10. For example, the measurement module 50 can be implemented in a control module of a vehicle or in a test equipment at a manufacturing plant, laboratory, or a service facility. The measurement module 50 comprises a current measurement circuit 52, a plurality of voltage measurement circuits 54, a plurality of temperature measurement circuits, and an SOC estimation circuit 58.

In some examples, the measurement module 50 may not be a single module. For example, each module 16 and the pack 18 may comprise a measurement module similar to the measurement module 50.

The current measurement circuit 52 can measure a current I through the pack 18 (i.e., through the battery 10). The same current I flows through all the cells 12 in the pack 18. The voltage measurement circuits 54 can measure voltages across each group 14 of cells 12. The temperature measurement circuits 56 can measure temperatures of each group 14 of cells 12. The SOC estimation circuit 58 can estimate SOC of the battery 10, which is expressed as available capacity of the battery 10 as a function of a rated capacity of the battery 10. For example, the SOC can be estimated using an open circuit voltage of the battery 10 or can be estimated using a coulomb counting method.

In some examples, while not shown, an onboard battery management system (BMS) in the vehicle can be used to estimate SOC and to control charging/discharging voltages/currents of the battery. Further, the SOC may be estimated for the pack 18 and/or the groups 14 of cells 12.

The prognostic method of the present disclosure uses these measurements to compute various health indicators for each group 14 of cells 12. The prognostic method also computes a median value of each health indicator for each module 16. The health indicators for each group 14 are normalized based on the median values of the health indicators for the module 16 comprising the groups 14. The normalized health indicators are then used to detect faults (failure modes) of an electrolyte in the cells 12 in each group 14 as described below in detail.

FIG. 1B schematically shows an example of the cell 12. The cell 12 comprises a cathode (K+) 102, an anode (A−) 104, a separator 106, an electrolyte 108, and current collectors 110, 112. The cathode 102 is the positive electrode. The anode 104 is the negative electrode. During charging of the battery 10, in each cell 12, lithium ions flow from the cathode 102 to the anode 104 through the separator 106 and the electrolyte 108 as shown by arrow 120. During discharging (i.e., when supplying power from the lithium-ion battery 10 to a load such as a subsystem of a vehicle), lithium ions flow from the anode 104 to the cathode 102 through the separator 106 and the electrolyte 108 as shown by arrow 122.

The electrolyte 108 conducts ions movement between electrodes inside the battery 10. The electrolyte 108 can fail due to various reasons. The failure can occur during manufacturing of the battery 10, storage of the battery 10 (e.g., in storage facilities after manufacturing and before shipping the battery 10, in parked vehicles, etc.), and use of the battery 10 in vehicles for an extended period of time.

Broadly, the electrolyte faults are categorized as faults due to low volume (e.g., due to leakage) of the electrolyte 108 (e.g., due to physical damage to the battery 10, which causes the leakage), moisture seeping into the electrolyte 108 (e.g., due to physical damage to the battery), and aging of the electrolyte 108. Throughout the present disclosure, these three types of faults of the electrolyte 108 are also called failure modes of the electrolyte 108: low volume fault or low volume failure mode, moisture fault or moisture failure mode, and aging fault or aging failure mode.

The low volume fault can occur during manufacturing of the battery 10 if less amount of electrolyte 108 is added to the battery 10 before sealing the battery 10. During storage or use of the battery 10, the low volume fault can occur if the electrolyte 108 leaks due to physical damage to the battery 10 while in storage or in the vehicle. The moisture fault can occur if the electrolyte 108 is exposed to the environment before adding the electrolyte 108 to the battery 10 during manufacturing. During storage or use, the moisture fault can occur if moisture seeps into the electrolyte 108 through openings (e.g., holes) in the battery 10 created by physical damage to the battery 10 while in storage or in the vehicle. The aging fault can occur during manufacturing if aged electrolyte 108 is added to the battery 10 during manufacturing. During storage or use, the aging fault can occur if the battery 10 is stored and remains unused for an extended period of time before or during the use of the battery 10 in the vehicle.

Electrolyte failures may cause performance degradation or even ignition or explosion due to corrosive nature of the electrolyte 108. Electrolyte faults can be detected offline (i.e., with the battery 10 outside the vehicle, for example, at a service facility, in a laboratory, etc.). The offline methods used to detect electrolyte faults involve using test apparatus such as a spectrometer or equipment used to measure conductivity of the electrolyte 108. The offline fault detection methods are difficult to use in vehicles.

Further, using the same standards as those used in the offline fault detection methods to prognose different electrolyte faults can be challenging due to the various electrolyte failure modes. For example, voltage-time scatter plots for a healthy electrolyte and the three failure modes of the electrolyte are indistinguishably close to each other. Therefore, distinguishing faulty electrolyte from healthy electrolyte and isolating the type of fault (failure mode) can be challenging. While there are several health indicators used to determine the health of the battery 10, the performance of these health indicators for detecting electrolyte failures and different failure modes is not well-established and is largely unknown in the art.

Furthermore, if only one cell 12 in a group 14 or a module 16 is faulty, the health indicators used to determine the health of the battery 10 do not deviate distinguishably. Instead, to identify the failing cell or cell group, the type of electrolyte fault, and the severity of the electrolyte fault, different health indicators need to be combined, normalized to median values of the health indicators for each module 16, and compared to respective thresholds. Thereafter, to declare a fault based on the comparisons, different types of logic (e.g., conservative logic, lenient logic, or a combination thereof) need to be used.

The present disclosure provides a prognostic method that uses a combination of various health indicators to detect the three types of electrolyte faults (failure modes): low volume (leaking), moisture, and aging. The prognostic method uses three sets of health indicators in combination with thresholding and decision tree logic to detect the three failure modes (faults), respectively. Some of the health indicators used are common to two or all three sets but have a different impact on the detection of the respective fault type when used in combination with other health indicators in each set.

The fault detection using the prognostic method described below is performed for each group 14 of the cells 12. That is, the prognostic method of the present disclosure detects electrolyte faults at cell group level and not for the battery as a whole. Thus, for each group 14 of the cells 12, the current through the battery 10 is measured, the voltage across the cells 12 in the group 14 is measured, the temperature of the group 14 of cells 12 is measured, and the SOC of the battery 10 is measured. Then the measurements for each group 14 are used to generate various health indicators. The health indicators are grouped into three sets for detecting the three types of electrolyte faults.

In each set, the health indicators are normalized based on median values of the health indicators for the module 16 comprising the group 14 of cells 12. The median values are not predetermined or pre-calibrated. Rather, the median values are calculated in real time when the health indicators are computed. Since the health indicators and the median values are computed based on the measurements of the battery 10 taken at the same time (e.g., during the same charge/discharge cycle), the health indicators and the median values reflect the same aging and other environmental effects that affect the battery 10. After normalization, the health indicators are compared to respective thresholds. Thereafter, different types of logic are used to declare a fault.

To detect electrolyte faults at cell group level rather than at the battery level, the selected health indicators and thresholds are not merely design choices. Rather, the health indicators and thresholds are selected empirically by analyzing the impact of each type of electrolyte fault on each health indicator and on different combinations of health indicators and selecting the specific health indicators and combinations based on the analyses. Other approaches for the selection include using machine learning techniques such as random forest, support vector machine (SVM), neural networks, deep neural networks, and so on.

One of the electrical parameters of the battery 10 that is affected by any of the three failure modes of the electrolyte 108 is an internal resistance of the battery 10 given by the following equation:

$${R}_{internal} = {R}_{SEI} + \frac{RT}{α F} ( \frac{1}{2 {aL}_{s} {SFkC}_{e} ( {C}_{s , max} - {C}_{e , s} ) {C}_{e , s}} ) + ( \frac{L}{2 {K}^{eff} S} )$$

where Cₑ is the concentration of the electrolyte 108, L is the length of the path of the electrolyte 108 (i.e., thickness or width of the battery), K^{eff} is the conductivity of the electrolyte 108, and Lₛ is the thickness of the solid phase (electrode).

Electrolytes typically comprise a lithium salt solution such as a lithium salt and a solvent. One or more failure modes can impact one or more parameters of the above equation, which in turn changes the internal resistance of the battery 10. For example, due to aging of the electrolyte 108, the solvent used in the electrolyte 108 can deteriorate and decompose, which increases the concentration Ce of the lithium salt in the electrolyte 108. Low volume of the electrolyte 108 may reduce L, and moisture seeping into the electrolyte 108 can change concentration Ce of the electrolyte 108. Length (L) impacts cell resistance, capacitance, and pack isolation resistance of the battery 10. The concentration (Ce) of the electrolyte 108 changes the resistance and capacity of the battery 10.

Changes in the internal resistance of the battery 10 is reflected in current and voltage measurements of the battery 10. Further, environmental conditions such as ambient temperature and temperature of the battery 10 can also change the internal resistance of the battery 10. However, measuring only these electrical parameters of the battery 10 cannot indicate an electrolyte fault since the changes in these electrical parameters due to an electrolyte fault in one or a few cells among a large number of cells in the battery 10 does not cause a measurable deviation in these electrical parameters of the battery 10. Instead, by using the prognostic method of the present disclosure, different health parameters can be computed, normalized, and used to detect electrolyte faults as follows.

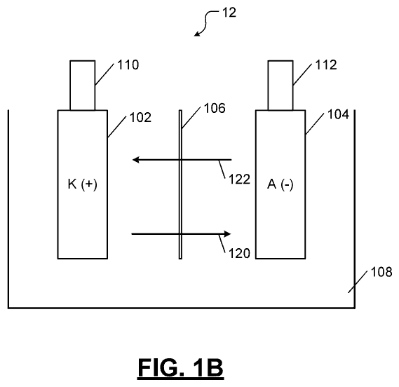

FIG. 2 shows a system 200 that uses the prognostic method of the present disclosure to detect electrolyte faults in the cells of a lithium-ion battery in a vehicle 202. The system 200 comprises the vehicle 202, a distributed communication system 204, a server 206, a service facility 208-1 (e.g., a car dealership or service station), and a manufacturing facility 208-2 (e.g., battery manufacturing plant, vehicle assembly plant, battery testing laboratory, etc.). The service facility 208-1 and the manufacturing facility 208-2 can be collectively called the external facilities 208 or simply the facilities 208.

The prognostic method of the present disclosure described below can be performed in the vehicle 202 or at the external facilities 208 (e.g., on a laptop or a handheld device). The prognostic method can be at least partly performed in the server 206 (also called remote server or server in a cloud). For example, data (e.g., current, voltage, temperature, and SOC measurements) from the battery 210 can be transmitted from the vehicle 202 and from the external facilities 208 to the server 206, which analyses the data and provides the prognosis using the prognostics method of the present disclosure.

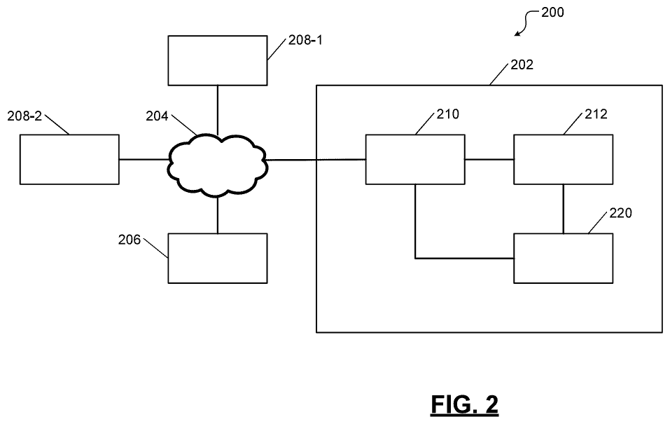

The vehicle 202 comprises a lithium-ion battery (the battery) 210, a plurality of vehicle subsystems 212, and a control module 220. The battery 210 is similar to the battery 10 shown and described above with reference to FIGS. 1A and 1B. The battery 210 supplies power to various vehicle subsystems 212 of the vehicle 202. The vehicle subsystems 212 comprise various electrical, mechanical, and electromechanical subsystems of the vehicle 202. Non-limiting examples of the vehicle subsystems 212 include a propulsion subsystem comprising one or more motors used to propel the vehicle 202, steering subsystem, braking subsystem, suspension subsystem, infotainment subsystem, heating, ventilation, and cooling (HVAC) subsystem, and so on. The control module 220 communicates with the battery 210 and the vehicle subsystems 212 and controls the vehicle subsystems 212. The control module 220 is shown and described in further detail with reference to FIG. 3.

The distributed communication system 204 comprises one or more networks (wired and/wireless) such as the Internet, local and/or wide area networks, and so on. The vehicle 202 (e.g., the control module 220) communicates with the server 206 via the distributed communication system 204. A computing device such as a laptop or a handheld device at the external facilities 208 communicates with the server 206 via the distributed communication system 204.

While not shown, a handheld device such as a smartphone can also be used in the vehicle 202. For example, the handheld device in the vehicle 202 can communicate with the control module 220 via Bluetooth. The handheld device in the vehicle 202 can also communicate with the server 206 and the external facilities 208 via the distributed communication system 204.

FIG. 3 shows the control module 220 of the vehicle 202. The control module 220 comprises a measurement module 222 and a prognostics module 230. The measurement module 222 is similar to the measurement module 50 shown and described above with reference to FIG. 1B. The prognostics module 230 comprises a health indicator computing module (HI module) 232, a normalization module 234, and a fault detection module 236.

The measurement module 222 measures (e.g., senses) various parameters (e.g., current, voltage, temperature, and SOC measurements) of the battery 210. The HI module 232 computes various health indicators of the battery 210 (described below) based on the parameters measured by the measurement module 222. The normalization module 234 normalizes the health indicators of the battery 210 as described below. The fault detection module 236 detects whether the battery 210 exhibits any of the three electrolyte failure modes described above. The operations of the prognostics module 230 including the computation and grouping of the health indicators, normalizing the health indicators, and detecting the failure modes are described below in detail.

The prognostics module 230 can also be implemented in a computing device such as a laptop or a handheld device at the external facilities 208 and in the server 206. Thus, the prognostic method of the present disclosure can be performed entirely in the vehicle 200 and entirely at the external facilities 208. The prognostics method of the present disclosure can also be performed partially in the vehicle 200 and partially at the external facilities 208 in conjunction with the server 206. For example, the measurements can be made in the vehicle 202 or at the external facilities 208 and can be sent to the server 206 for analysis. The server 206 can send result of the analysis such as whether the battery 210 is faulty and needs to be serviced or replaced to the vehicle 202 or to the external facilities 208. The results can be displayed on a dashboard of the vehicle 202 or on the handheld device in the vehicle. The results can be displayed on the handheld device or test equipment at the external facilities 208. A service technician or a person at the external facilities 208 can decide whether to service or discard the battery 210.

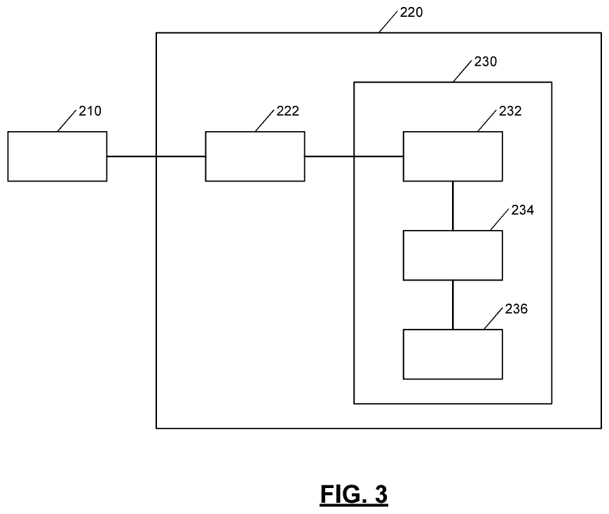

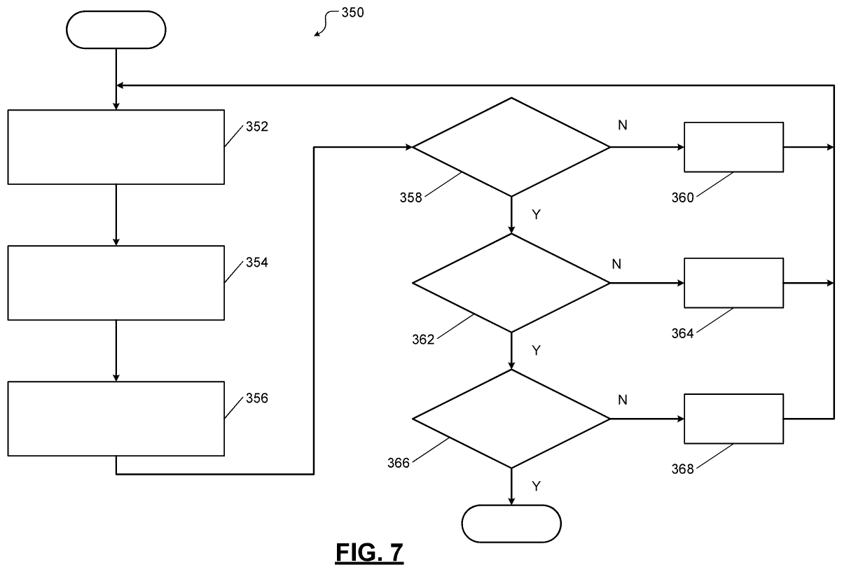

FIG. 4 shows a method 300 performed by the control module 220. At 302, the measurement module 222 measures (e.g., senses) various parameters (e.g., voltage, current, temperature, and SOC) of the battery 210. At 304, the HI module 232 computes various health indicators of the battery 210 based on the parameters measured by the measurement module 222. The health indicators are described below. At 306, the normalization module 234 normalizes the health indicators of the battery 210 as shown and described below with reference to FIG. 7.

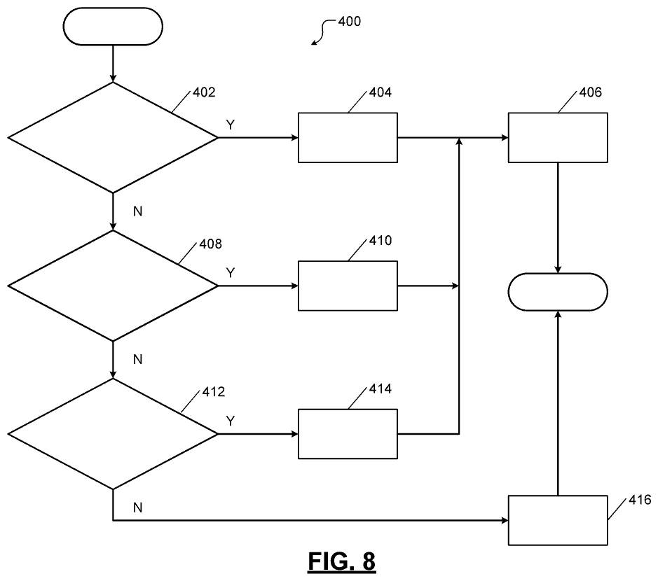

At 308, the fault detection module 236 groups the normalized health indicators in three sets to detect the three failure modes of the electrolyte 208, respectively. In some examples, the health indicators may be grouped before normalization. At 310, in each set, the fault detection module 236 compares the normalized health indicators to respective thresholds selected for the type of electrolyte fault to be detected by the respective set of normalized health indicators. At 312, the fault detection module 236 detects whether the battery 210 exhibits any of the three failure modes described above (i.e., detects one or more types of faults in the electrolyte 208 based on the comparisons). Steps 310 and 312 are shown and described below in further detail with reference to FIG. 8.

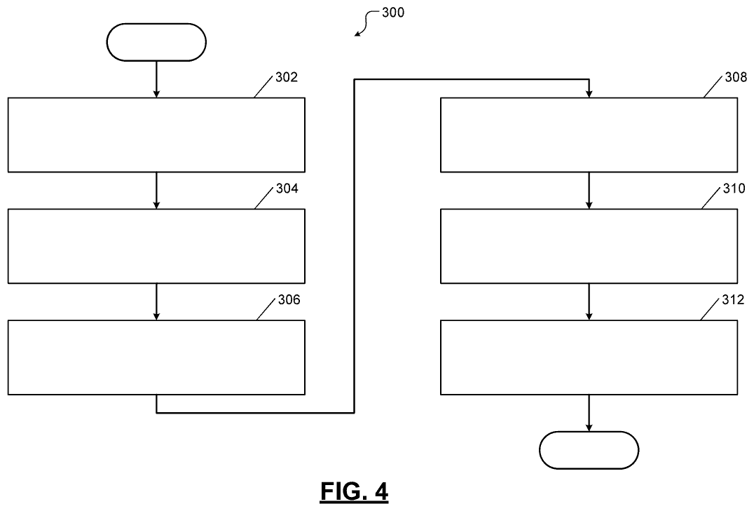

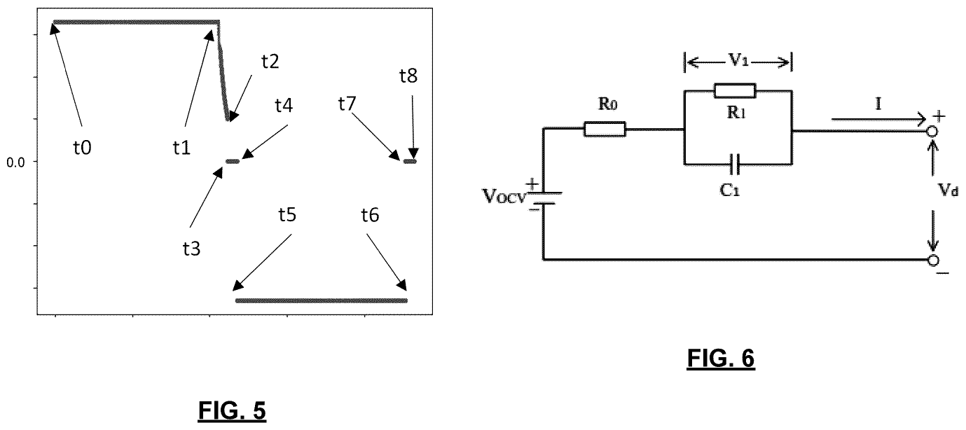

Before describing the health indicators in detail, various time periods during the charging and discharging cycles of the battery 210 are shown and described with reference to FIG. 5. Some of the health indicators are measured during these time periods. Additionally, an equivalent circuit model (ECM) of the battery 210 is shown and described with reference to FIG. 6. Various battery parameters used to derive some of the health indicators are shown and described with reference to FIG. 6.

FIG. 5 shows a graph of current versus time during charging and discharging cycles of the battery 210 based on which the HI module 232 computes various health indicators for the cells 12 of the battery 210. From time t0 to t1, the battery 210 is being charged with constant current. Thus, time t0 to t1 is a constant current charging period of the battery 210 during which the voltage of the battery 210 increases. From time t1 to t2, the battery 210 is being charged at a constant voltage. Thus, time t1 to t2 is a constant voltage charging period of the battery 210 during which the current of the battery 210 decreases. From time t3 to t4, the battery 210 is at rest (i.e., not connected to any load; neither charging nor discharging).

From time t5 to t6, the battery 210 is being discharged when the battery 210 supplies a constant current to a load (e.g., a motor of the propulsion subsystem of the vehicle 202). The voltage of the battery 210 decreases during time t5 to t6. From time t7 to t8, the battery 210 is at rest (i.e., not connected to any load; neither charging nor discharging). The time periods t2 to t3 and t6 to t7 are called transition periods to the rest state of the battery 210.

FIG. 5 shows the battery current during charging and discharging cycles for a healthy battery. As the battery 210 degrades (e.g., due one or more electrolyte faults), the battery voltage and current during charging and discharging cycles change. Current level is controlled during constant current charging and during discharging. Current changes during contact voltage charging. The times t1-t7 shift. These changes and shifts, which reflect one or more electrolyte faults, are captured by the various health indicators described below.

FIG. 6 shows an equivalent circuit model (ECM) of the battery 210. In the ECM, the battery 210 is shown as having an open circuit voltage (OCV), which is the voltage across the cathode and the anode of the battery 210 when no load is connected to the battery 210. R0 (also called ECM_R0) is the ohmic internal resistance of the battery 210. R1 (also called ECM_R1) is the polarization internal resistance of the battery 210. C1 is the polarization capacitance of the battery 210. V1 is the polarization voltage of the battery 210. I is the discharge current of the battery 210. and Vd is the terminal voltage of the battery 210. As the battery 210 degrades (e.g., due one or more electrolyte faults), these ECM parameters of the battery 210 also change. The changes in these ECM parameters of the battery 210, which reflect one or more electrolyte faults, are captured by the various health indicators described below.

The fault detection module 236 uses a first set of health indicators (HI set 1) to detect the low volume fault or low volume failure mode of the electrolyte 208. The fault detection module 236 uses a second set of health indicators (HI set 2) to detect the moisture fault or moisture failure mode of the electrolyte 208. The fault detection module 236 uses a third set of health indicators (HI set 3) to detect the aging fault or aging failure mode of the electrolyte 208. The values of these health indicators change due to any of the failure modes of the electrolyte 108.

The Hi module 232 computes the health indicators in the first set of health indicators (HI set 1) based on the measurements made by the measurement module 222 as follows. The HI set 1 comprises the following five health indicators:
(i) A health indicator called a static resistance Rs of the battery 210 during a discharge cycle of the battery 210 is denoted by Rs_dchg. The health indicator Rs_dchg is calculated using the following formula:

$$Static resistance dchg = \frac{{V}_{t 7} - {V}_{t 6}}{{I}_{t 7} - {I}_{t 6}}$$

(ii) A health indicator called a variation in capacity of the battery 210 measured in terms of charge dQ required to increase the voltage of the battery 210 from a first value to a second value during constant current charging, is denoted by dQ_cc_chg. The first and second voltage values are selected between time t0 to t1 during constant current charging. The health indicator dQ_cc_chg is calculated using the following formula:

$$dQ\_cc \_chg = {\int }_{t 0}^{t 1} Idt$$

If the capacity of the battery 210 has decreased, the voltage of the battery 210 will rise from the first to the second value with less charge than the amount of charge needed to raise the voltage of the battery 210 from the first to the second value when the battery is at rated capacity. Thus, a lower value of dQ_cc_chg can be indicative of a fault.
(iii) A health indicator called a position of peak of rate of change of charge Q relative to voltage (dQ/dV) of the battery 210 relative to the voltage V of the battery 210 is denoted by dQ/dV_cc_chg_peak_position. The health indicator dQ/dV_cc_chg_peak_position denotes a peak position (i.e., a position of the peak value) of dQ/dV relative to the voltage V of the battery 210 during constant current charging period t0 to t1. The health indicator dQ/dV_cc_chg_peak_position is measured by plotting dQ/dV on x-axis and the voltage V on y-axis during constant current charging period t0 to t1. The health indicator dQ/dV_cc_chg_peak_position indicates the position or the value of V at which the peak of dQ/dV occurs during constant current charging period t0 to t1. The health indicator dQ/dV_cc_chg_peak_position is calculated using the following formula:

$$V = V max ( \frac{d}{dV} {\int }_{t 0}^{t 1} Idt ) \cdot index ]$$

A shift in the dQ/dV_cc_chg_peak_position (i.e., the voltage V at which the dQ/dV peak occurs) to the left or right along x-axis as compared to where the peak is for a healthy battery can be indicative of a fault.
(iv) A health indicator called a difference in energy between charging and discharging cycles of the battery 210 under a selected voltage range is denoted by dE. The health indicator energy difference (also called energy loss) dE is calculated using the following formula:

$$dE = {\int }_{t 0}^{t 2} VIdt - {\int }_{t 5}^{t 6} VIdt$$

(v) A health indicator called an ohmic internal resistance R0 of the battery 210 is denoted by ECM_R0. The health indicator ECM_R0 is calculated from the ECM shown in FIG. 6 during charging and discharging of the battery 210.

The Hi module 232 computes the health indicators in the second set of health indicators (HI set 2) based on the measurements made by the measurement module 222 as follows. The HI set 2 comprises the following six health indicators: The health indicators dQ_cc_chg and energy loss dE in HI set 2 are the same as in the HI set 1. In addition, the HI set 2 comprises the following four health indicators:
(i) A health indicator called a discharge duration for the battery 210 over a selected voltage range during a discharge cycle is denoted by dT_cc_dchg. The health indicator dT_cc_dchg is calculated using the following formula:

$$dT\_cc \_dchg = t 6 - t 5$$

The discharge duration over the selected voltage range will differ depending on the health of the battery 210.
(ii) A health indicator called a sum of voltages of the battery 210 during a constant current charging duration of a charging cycle of the battery 210 (from time t0 to t1) is denoted by Vsum_cc. The health indicator Vsum_cc is calculated using the following formula:

$${V}_{based} = {\sum }_{k = t 0}^{t 1} V ( k )$$

(iii) A health indicator called a peak value of rate of change of charge Q relative to voltage (dQ/dV) of the battery 210 relative to the voltage V of the battery 210 is denoted by dQ/dV_cc_chg_peak_value. The health indicator dQ/dV_cc_chg_peak_value denotes a peak value of dQ/dV relative to the voltage V of the battery 210 during constant current charging period t0 to t1. The health indicator dQ/dV_cc_chg_peak_value is measured by plotting dQ/dV on x-axis and the voltage V on y-axis during constant current charging period t0 to t1. The health indicator dQ/dV_cc_chg_peak_value indicates the peak value of dQ/dV during constant current charging period t0 to t1. The health indicator dQ/dV_cc_chg_peak_value is calculated using the following formula:

$$\frac{dQ}{dV} peak value = max ( \frac{d}{dV} {\int }_{t 0}^{t 1} Idt )$$

(iv) A health indicator called a polarization resistance R1 of the battery 210 is denoted by ECM_R1. The health indicator ECM_R1 is calculated from the ECM shown in FIG. 6 during charging and discharging of the battery 210.

The Hi module 232 computes the health indicators in the third set of health indicators (HI set 3) based on the measurements made by the measurement module 222 as follows. The HI set 3 comprises the following eleven health indicators: The five health indicators dQ_cc_chg, dT_cc_chg, energy loss dE, Vsum_cc, and ECM_R0 in HI set 3 are the same as in the HI sets 1 and 2. In addition, the HI set 3 comprises the following six health indicators:
(i) A health indicator called a loss in capacity (also called capacity loss) of the battery 210 due to aging of the battery 210 is denoted by dC. The health indicator dC is a difference in capacity of the battery 210 over a selected voltage range during charging and discharging. The health indicator dC is calculated using the following formula:

$$dC = {\int }_{t 0}^{t 2} Idt - {\int }_{t 6}^{t 5} Idt$$

(ii) A health indicator called a variation in (rate of change of) voltage V of the battery 210 is denoted by dV/dt. The health indicator dV/dt is measured over a selected voltage range during constant current charging of the battery 210. The health indicator dV/dt is calculated using the following formula:

$$dV / dt = \frac{{V}_{t 1} - {V}_{t 0}}{t 1 - t 0}$$

(iii) A health indicator called a logarithmic rate of change of current during a constant voltage charging duration of the battery 210 is denoted by d ln(I)/dt. The health indicator d ln(I)/dt is calculated using the following formulae.

During constant voltage charging of the battery (from t2 to t3), the current through the battery 210 follows the equation: ln(I)=at +ln(I(0)), where a is the slope of ln(I), i.e., a=d ln(I)/dt, which is the health indicator.

$${Let [ a , ln ( I ( 0 ) ) ]}^{T} = A , [ t , 1 ] = X$$

$$ln ( I ) = X * A$$

A can be calculated by least square method as follows:

$${X}^{T} ln ( I ) = {X}^{T} X * A$$

$${( {X}^{T} X )}^{- 1} {X}^{T} ln ( I ) = {( {X}^{T} X )}^{- 1} {X}^{T} X * A$$

$${( {X}^{T} X )}^{- 1} {X}^{T} ln ( I ) = A$$

A[0] is a

$$a = A [ 0 ] = \frac{dln ( I )}{dt} ,$$

which is the health indicator. The slope a changes due to one or more electrolyte faults.
(iv-vi) For the battery 210, relationships between charge Q and open circuit electrode potentials (EP) of anode and cathode (OCPan and OCPca) during constant current charging of the battery 210 can be mathematically derived using SOC curves plotted at two different charging rates. The electrode potentials are potentials of the electrodes cathode and anode relative to a third reference electrode and not relative to each other. The electrode potentials relative to a third reference electrode are derived mathematically without using a third reference electrode and without measuring the electrode potentials relative to a third reference electrode.

The electrode potentials (EP) are computed by the HI module 232 based on mathematical analyses of the measurements made by the measurement module 222. The electrode potentials are affected by one or more electrolyte faults. From the electrode potentials, three EP-based health indicators are mathematically derived by the HI module 232: loss of capacity (anode) denoted by EP_LoCan, loss of capacity (cathode) denoted by EP_LoCca, and loss of lithium inventory denoted by EP_LLI. These three health indicators change due to one or more electrolyte faults. Thus, changes in these three health indicators reflect one or more electrolyte faults.

The HI module 232 calculates all of the above health indicators for each cell group 14 in the battery 210. To calculate the above health indicators, the measurement module 222 measures the current through the battery 210, which is the same current that flows through all the cell groups 14 in the battery 210. The measurement module 222 measures the voltages across each cell group 14 in each module 16 in the battery 210. Thus, in the battery 210, if each of M modules 16 comprises G cell groups 14, the measurement module 222 measures M×G voltages across M×G cell groups 14. The measurement module 222 also measures temperatures of each of the M×G cell groups 14. The measurement module 222 measures the SOC of the battery 210.

All these measurements are made at the time of calculating the health indicators in the same charge/discharge cycle of the battery 210. Measurements from one charge/discharge cycle are not used to compute the health indicators in another charge/discharge cycle. Accordingly, the measurements and the health indicators calculated from the measurements reflect the same effects due to aging of the battery 210 and the same environmental effects (e.g., the ambient temperature, the temperature of the battery 210, etc.) on the battery 210.

The normalization module 234 normalizes each health indicator in the three sets of health indicators for each cell group 14 as follows. For each health indicator, the HI module 232 also calculates a corresponding median value of the health indicator for the module 16 that comprises the cell group 14. To normalize a health indicator for a cell group 14 in a module 16, the normalization module 234 subtracts the corresponding median health indicator for the module 16 from the health indicator of the cell group 14. The normalization is denoted by the following equation:

$$Normalized Indicator = Indicator [ i ] - baseline [ i ] where i is cycle number i = 1 , 2 , 3 … .$$

After each charge/discharge cycle of the battery 210, the index for the cycle number is increased by 1, and the same index (i.e., measurements and HI calculations made in the same charge/discharge cycle) is used for normalization of the health indicators.

FIG. 7 shows an example of a normalization method 350 (step 306 shown in FIG. 4) employed by the normalization module 234 to normalize the health indicators in the three sets of health indicators for each cell group 14 in each module 16. At 352, the HI module 232 computes a health indicator for each cell group 14 in a module 16 during a charge/discharge cycle of the battery 210.

At 354, the HI module 232 computes a median value of the health indicator for the module 16 comprising the cell group 14. For example, the HI module 232 computes an average of the values of the health indicator computed for all the cell groups 14 within the module 16 to provide the median value of the health indicator for the module 16. At 356, the normalization module 234 normalizes the health indicator for a cell group 14 in the module 16 by subtracting the median value of the health indicator from the value of the health indicator for the cell group 14.

At 358, the normalization module 356 determines if all of the health indicators in the three sets of health indicators for the cell group 14 are normalized. If all of the health indicators in the three sets of health indicators for the cell group 14 are not normalized, at 360, the normalization module 356 selects the next health indicator to normalize, and the method 350 returns to 352.

If all of the health indicators in the three sets of health indicators for the cell group 14 are normalized, at 362, the normalization module 356 determines if all of the health indicators in the three sets of health indicators are normalized for all of the cell groups 14 in the module 16. If all of the health indicators in the three sets of health indicators are not normalized for all of the cell groups 14 in the module 16, at 364, the normalization module 356 selects next cell group 14, and the method 350 returns to 352.

If all of the health indicators in the three sets of health indicators are normalized for all of the cell groups 14 in the module 16, at 366, the normalization module 356 determines if all of the health indicators are normalized for all the modules 16 in the battery 210. If all of the health indicators are not normalized for all the modules 16 in the battery 210, at 368, the normalization module 356 selects the next module 16, and the method 350 returns to 352. If all of the health indicators are normalized for all the modules 16 in the battery 210, the normalization of all of the health indicators for the battery 210 is complete, and the method 350 ends.

The fault detection module 236 groups the normalized health indicators in the three sets of normalized health indicators for each group 14 of cells 12 in the battery 210. The fault detection module 236 detects one or more of the three faults (failure modes) of the electrolyte for each group 14 of cells 12 in the battery 210. In one example, the fault detection module 236 can declare a fault based on a single fault (failure mode) detected in a single group 14 of cells 12. In another example, the fault detection module 236 can declare a fault if two or more faults (failure modes) are detected in a single group 14 of cells 12. In still another example, the fault detection module 236 can declare a fault only if all three faults (failure modes) are detected in a single group 14 of cells 12.

When detecting a fault (failure mode) in a group 14 of the cells 12, the fault detection module 236 compares each normalized health indicator in a corresponding set of normalized health indicators, which is used to detect the fault, to a corresponding threshold. In one example, the fault detection module 236 can declare a fault (detection of a failure mode) in a group 14 of cells 12 if a single normalized health indicator in the corresponding set of normalized health indicators exceeds a corresponding threshold. In another example, the fault detection module 236 can declare a fault (detection of a failure mode) in a group 14 of cells 12 if two or more normalized health indicators in the corresponding set of normalized health indicators exceed respective thresholds. In still another example, the fault detection module 236 can declare a fault (detection of a failure mode) in a group 14 of cells 12 if all of the normalized health indicators in the corresponding set of normalized health indicators exceed respective thresholds.

The fault detection module 236 can be configured to declare a fault using any combination of detecting one or more failure modes and one or more normalized health indicators exceeding respective thresholds. For example, in the factory, before shipping the battery 210, the fault detection module 236 can be configured to declare a fault after detecting a single failure mode and a single normalized health indicator exceeding a corresponding threshold to detect a failure mode. At a service station, the fault detection module 236 can be configured to indicate to a technician which failure mode or modes are detected and which normalized health indicator or indicators have exceeded corresponding thresholds. The technician can decide whether to service or replace the battery 210 based on the normalized health indicators that exceeded the thresholds and the failure modes detected.

In the vehicle 202, the fault detection module 236 can be configured to provide different levels of warnings (alerts) on a dashboard of the vehicle 202 (or on a handheld device such as a smartphone) based on which failure mode or modes are detected and which normalized health indicator or indicators have exceeded corresponding thresholds. Accordingly, recalls and visits to service station can be optimized. For example, if the electrolyte in the battery 210 is leaking, the warning can be severe (of the highest level) since electrolyte leakage can cause corrosion or fire. The warning can be less severe if the battery 210 is simply aging and performance of the battery 210 is slowly degrading.

Further, within a failure mode, the warnings (alerts) can be further graded. For example, the warning due to leakage failure mode can be severe if leaks in two or more groups 14 of cells 12 or in two or more modules 16 are detected but less severe if only a single leak is detected. For example, the warning due to moisture failure mode can be severe if the moisture seepage is rapidly increasing based on daily monitoring but less severe if moisture seepage is slow. For example, the warning due to aging failure mode can be severe if the aging based on daily monitoring indicates that the battery 210 is nearing the end of its life prematurely but less severe if aging is slow, and so on.

Thus, the declaration that a cell group 14 and/or the battery 210 is healthy or faulty is not a binary decision based on a single health indicator or a single type of electrolyte fault. Rather, the declaration is graded into multiple levels of severity of the detected fault and/or the failure of the detected health indicator. In one example, the battery 210 can be declared faulty if a single electrolyte fault is detected based on a failure of a single health indicator. In other examples, the battery 210 may still be declared healthy even if an electrolyte fault based on a failure of a health indicator is detected. The fault detection module 236 determines a health of the battery 210 based on which of the electrolyte faults is detected and which of the normalized health indicators exceed respective predetermined thresholds.

Further, the prognostic method is not limited to only detecting declaring electrolyte faults for service purposes. The output of the prognostics module 230 can also be used to modify vehicle controls by modifying battery usage. For example, when an electrolyte fault is detected during battery usage in the vehicle, the control module 220 can reduce power supplied from the battery 210 to one or more subsystems 212 of the vehicle 202. For example, the control module 220 can maintain power supply from the battery 210 to the subsystems 212 in a prioritized manner. For example, initially, until the battery 210 is serviced after an electrolyte fault is detected, the power supply to comfort systems such as the HVAC subsystem and the infotainment subsystem may be reduced while maintaining power supply to the propulsion, steering, and braking subsystems of the vehicle 202.

While the above-mentioned permutations and many other combinations of the health indicators can be used to detect and declare electrolyte faults, FIG. 8 shows an example of a most robust (conservative) method 400 of declaring a fault in which a single normalized health indicator in a single set of normalized health indicators leads to a declaration that the battery 210 is faulty. In the method 400, the battery 210 is declared healthy (i.e., without any of the three failure modes), only if all of the normalized health indicators leads in all of the three sets of the normalized health indicators are less than or equal to corresponding thresholds (i.e., if not a single normalized health indicator exceeds its threshold). The thresholds are predetermined in the factory before the battery 210 is shipped in the vehicle 202. The method 400 is performed by the fault detection module 236 when performing steps 310 and 312 of the method 300 shown in FIG. 4.

In FIG. 8, at 402, the fault detection module 236 determines if any normalized health indicator in the first set of normalized health indicators (set 1) exceeds a corresponding threshold. If any normalized health indicator in the first set of normalized health indicators (set 1) exceeds a corresponding threshold, at 404, the fault detection module 236 declares that the first type of fault (low volume failure mode of the electrolyte 108) is detected. At 406, the fault detection module 236 declares that the battery 210 is faulty.

If none of the normalized health indicators in the first set of normalized health indicators (set 1) exceeds a corresponding threshold (i.e., if all of the normalized health indicators in the first set of normalized health indicators (set 1) are less than or equal to respective thresholds), at 408, the fault detection module 236 determines if any normalized health indicator in the second set of normalized health indicators (set 2) exceeds a corresponding threshold. If any normalized health indicator in the second set of normalized health indicators (set 2) exceeds a corresponding threshold, at 410, the fault detection module 236 declares that the second type of fault (moisture failure mode of the electrolyte 108) is detected. At 406, the fault detection module 236 declares that the battery 210 is faulty.

If none of the normalized health indicators in the second set of normalized health indicators (set 2) exceeds a corresponding threshold (i.e., if all of the normalized health indicators in the second set of normalized health indicators (set 2) are less than or equal to respective thresholds), at 412, the fault detection module 236 determines if any normalized health indicator in the third set of normalized health indicators (set 3) exceeds a corresponding threshold. If any normalized health indicator in the third set of normalized health indicators (set 3) exceeds a corresponding threshold, at 414, the fault detection module 236 declares that the third type of fault (aging failure mode of the electrolyte 108) is detected. At 406, the fault detection module 236 declares that the battery 210 is faulty.

If none of the normalized health indicators in the third set of normalized health indicators (set 3) exceeds a corresponding threshold (i.e., if all of the normalized health indicators in the third set of normalized health indicators (set 3) are less than or equal to respective thresholds), at 416, the fault detection module 236 declares that the battery 210 is healthy.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A system comprising:
a measurement module configured to measure a plurality of parameters associated with a battery comprising cells including an electrolyte;
a health indicator module configured to generate a plurality of health indicators based on the measured parameters;
a normalization module configured to normalize the health indicators and to combine the normalized health indicators into different sets to detect different types of faults associated with the electrolyte; and
a fault detection module configured to detect one or more of the faults associated with the electrolyte based on one or more of the normalized health indicators in one or more of the sets.

2. The system of claim 1 wherein the types of faults associated with the electrolyte comprise a first fault due to the electrolyte leaking from one or more of the cells, a second fault due to moisture seeping into one or more of the cells, and a third fault due to the electrolyte aging in one or more of the cells.

3. The system of claim 1 wherein:
the battery comprises a plurality of modules, each module comprising a plurality of groups of cells, and each group comprising one or more of the cells; and
the fault detection module is configured to detect one or more of the faults associated with the electrolyte in one of the groups of cells.

4. The system of claim 1 wherein:
the battery comprises a plurality of modules, each module comprising groups of cells, and each group comprising one or more of the cells; and
the normalization module is configured to normalize one of the health indicators for one of the groups of cells in one of the modules by subtracting a median value of the one of the health indicators for the one of the modules from the one of the health indicators for the one of the groups of cells.

5. The system of claim 4 wherein the health indicator module is configured to generate the one of the health indicators and the median value of the one of the health indicators based on the parameters measured in the same charge/discharge cycle of the battery.

6. The system of claim 1 wherein the fault detection module is configured to detect one of the faults based on one or more of the normalized health indicators in one of the sets exceeding a respective predetermined threshold and to generate an alert upon detecting the one of the faults.

7. The system of claim 1 wherein the fault detection module is configured to determine a health of the battery based on which of the faults is detected and which of the normalized health indicators exceed respective predetermined thresholds.

8. The system of claim 1 wherein:
the battery comprises a plurality of modules, each module comprising groups of cells, and each group comprising one or more cells;
the measurement module is configured to measure the parameters including a current through the battery, voltages across each group of cells, temperatures of each group of cells, and a state of charge of the battery;
the health indicator module is configured to generate the health indicators for each group of cells; and
the normalization module is configured to normalize each of the health indicators for one of the groups of cells based on median values of each of the health indicators for the one of the groups of cells.

9. The system of claim 1 wherein one of the sets of the normalized health indicators for detecting a fault due to the electrolyte leaking from one or more of the cells comprises: (i) a static resistance of the battery during a discharge cycle of the battery, (ii) a variation in capacity of the battery during constant current charging of the battery, (iii) a position of a peak value of dQ/dV relative to voltage V of the battery during constant current charging of the battery, (iv) a difference in energy between charging and discharging cycles of the battery, and (v) an ohmic internal resistance of the battery during charging and discharging of the battery.

10. The system of claim 1 wherein one of the sets of the normalized health indicators for detecting a fault due to moisture seeping into one or more of the cells comprises: (i) a variation in capacity of the battery during constant current charging of the battery, (ii) a difference in energy between charging and discharging cycles of the battery, (iii) a discharge duration for the battery, (iv) a sum of voltages of the battery during constant current charging of the battery, (v) a peak value of dQ/dV relative to voltage V of the battery during constant current charging of the battery, and (vi) a polarization resistance during charging and discharging of the battery.

11. The system of claim 1 wherein one of the sets of the normalized health indicators for detecting a fault due to the electrolyte aging in one or more of the cells comprises: (i) a variation in capacity of the battery during constant current charging of the battery, (ii) a discharge duration for the battery, (iii) a sum of voltages of the battery during constant current charging of the battery, (iv) a difference in energy between charging and discharging cycles of the battery, (v) a difference in capacity of the battery during charging and discharging of the battery, (vi) a rate of change of voltage of the battery during constant current charging of the battery, (vii) a logarithmic rate of change of current during constant voltage charging of the battery, (viii) loss of capacity of anode during constant current charging of the battery, (ix) loss of capacity of cathode during constant current charging of the battery, (x) loss of lithium inventory during constant current charging of the battery, and (xi) an ohmic internal resistance of the battery during charging and discharging of the battery.

12. A vehicle comprising the battery and the system of claim 1 wherein the fault detection module is configured to output an indication of the one or more of the faults associated with the electrolyte to control power supplied from the battery to one or more subsystems of the vehicle.

13. A method comprising:
measuring a plurality of parameters associated with a battery comprising cells including an electrolyte;
generating a plurality of health indicators based on the measured parameters;
normalizing the health indicators and to combine the normalized health indicators into different sets to detect different types of faults associated with the electrolyte; and
detecting one or more of the faults associated with the electrolyte based on one or more of the normalized health indicators in one or more of the sets.

14. The method of claim 13 wherein the types of faults associated with the electrolyte comprise a first fault due to the electrolyte leaking from one or more of the cells, a second fault due to moisture seeping into one or more of the cells, and a third fault due to the electrolyte aging in one or more of the cells.

15. The method of claim 13 wherein the battery comprises a plurality of modules, each module comprising a plurality of groups of cells, and each group comprising one or more of the cells; the method further comprising detecting one or more of the faults associated with the electrolyte in one of the groups of cells.

16. The method of claim 13 wherein the battery comprises a plurality of modules, each module comprising groups of cells, and each group comprising one or more of the cells; the method further comprising normalizing one of the health indicators for one of the groups of cells in one of the modules by subtracting a median value of the one of the health indicators for the one of the modules from the one of the health indicators for the one of the groups of cells.

17. The method of claim 16 further comprising generating the one of the health indicators and the median value of the one of the health indicators based on the parameters measured in the same charge/discharge cycle of the battery.

18. The method of claim 13 further comprising detecting one of the faults based on one or more of the normalized health indicators in one of the sets exceeding a respective predetermined threshold and to generate an alert upon detecting the one of the faults.

19. The method of claim 13 further comprising determining a health of the battery based on which of the faults is detected and which of the normalized health indicators exceed respective predetermined thresholds.

20. The method of claim 13 wherein the battery comprises a plurality of modules, each module comprising groups of cells, and each group comprising one or more cells; the method further comprising:
measuring the parameters including a current through the battery, voltages across each group of cells, temperatures of each group of cells, and a state of charge of the battery;
generating the health indicators for each group of cells; and
normalizing each of the health indicators for one of the groups of cells based on median values of each of the health indicators for the one of the groups of cells.
